(19) United States
(12) Patent Application Publication
(10) Pub. No.: US 2024/0096853 A1
(43) Pub. Date: Mar. 21, 2024

(54) SEMICONDUCTOR STRUCTURE AND METHOD FOR MANUFACTURING SAME

(71) Applicant: CHANGXIN MEMORY TECHNOLOGIES, INC., Hefei City (CN)

(72) Inventors: Yuan FANG, Hefei City (CN); Yanwu WANG, Hefei City (CN)

(73) Assignee: CHANGXIN MEMORY TECHNOLOGIES, INC., Hefei City (CN)

(21) Appl. No.: 18/525,467

(22) Filed: Nov. 30, 2023

Related U.S. Application Data
(63) Continuation of application No. PCT/CN2022/123998, filed on Oct. 9, 2022.

(30) Foreign Application Priority Data
Sep. 19, 2022 (CN) 202211139021.2

(51) Int. Cl. H01L 25/065; H01L 23/00; H01L 25/00

(52) U.S. Cl. CPC H01L 25/0657; H01L 24/16; H01L 25/50; H01L 24/05; H01L 2224/05025; H01L 2224/05082; H01L 2224/05124; H01L 2224/05573; H01L 2224/16145; H01L 2225/06513; H01L 2225/06544

(57) ABSTRACT

A semiconductor structure includes a plurality of dies. The plurality of dies are stacked sequentially along a first direction. The first direction is a direction perpendicular to a plane of the dies. Each of the dies includes a base and n first conductive structures penetrating the base along the first direction, where n is greater than or equal to 2. In at least one group of the corresponding first conductive structures in the dies, projections of the group of the first conductive structures in two adjacent layers of the dies along the first direction are not overlapped with each other.

### CROSS-REFERENCE TO RELATED APPLICATIONS

This is a continuation of International Application No. PCT/CN2022/123998 filed on Oct. 9, 2022, which claims priority to Chinese Patent Application No. 202211139021.2 filed on Sep. 19, 2022. The disclosures of the above-referenced applications are hereby incorporated by reference in their entirety.

### BACKGROUND

Generally, high bandwidth memory (HBM) dies may be stacked on the upper surface of the package base. The HBM dies may be electrically connected with the package base via conductive bumps. With the development of 3D package stacking technology, requirements of high bandwidth and low power consumption promote higher die stacking and denser through-silicon via (TSV) interconnections. However, the integration of HBM is increased with the crosstalk effect between signals.

### SUMMARY

The invention relates to the technical field of semiconductors, in particular to a semiconductor structure and a method for manufacturing the same.

In view of this, embodiments of the disclosure provide a semiconductor structure and a method for manufacturing the same.

According to the first aspect of the disclosure, a semiconductor structure is provided, which includes a plurality of dies.

The plurality of dies are stacked sequentially along a first direction. The first direction is a direction perpendicular to a plane of the dies.

Each of the plurality of dies includes a base and n first conductive structures.

The n first conductive structures penetrate the base along the first direction, and n is greater than or equal to 2.

In at least one group of the corresponding first conductive structures in all the dies, projections of the group of the first conductive structures in two adjacent layers of the dies along the first direction are not overlapped with each other.

According to the second aspect of the embodiments of the disclosure, a method for manufacturing a semiconductor structure is provided, including the following operation.

A plurality of dies stacked sequentially along a first direction are formed. The first direction is a direction perpendicular to a plane of the dies.

Forming each of the plurality of dies includes the following operations.

A base is provided.

n first conductive structures are formed. The n first conductive structures penetrate the base along the first direction, and n is greater than or equal to 2.

In at least one group of the corresponding first conductive structures in the dies, projections of the group of the first conductive structures in two adjacent layers of the dies along the first direction are not overlapped with each other.

### BRIEF DESCRIPTION OF THE DRAWINGS

In order to more clearly illustrate the technical solution in the embodiments of the disclosure or in the conventional techniques, the drawings needed in the embodiments will be briefly described below. It will be apparent that the drawings described below are only some embodiments of the disclosure. Other drawings may be obtained based on these drawings without creative effort by a person of ordinary skill in the art.

FIG. 1 is a schematic diagram of a semiconductor structure provided by an embodiment of the disclosure.

FIG. 2 is a spatial diagram of first conductive structures provided by an embodiment of the disclosure.

FIG. 3 is a schematic diagram of first conductive structures provided by the embodiment of the disclosure.

FIG. 4 is a schematic diagram of connection between two adjacent layers of dies through first interconnects.

FIG. 5 is a schematic structural diagram of each layer of dies provided by an embodiment of the disclosure.

FIG. 6 is a perspective view of a semiconductor structure provided by another embodiment of the disclosure.

FIG. 7 is a flowchart of a method for manufacturing a semiconductor structure provided by an embodiment of the disclosure.

FIG. 8A is a first schematic structural diagram during a process for manufacturing a semiconductor structure provided by an embodiment of the disclosure.

FIG. 8B is a second schematic structural diagram during a process for manufacturing a semiconductor structure provided by an embodiment of the disclosure.

FIG. 8C is a third schematic structural diagram during a process for manufacturing a semiconductor structure provided by an embodiment of the disclosure.

FIG. 9A is a fourth schematic structural diagram during a process for manufacturing a semiconductor structure provided by an embodiment of the disclosure.

FIG. 9B is a fifth schematic structural diagram during a process for manufacturing a semiconductor structure provided by an embodiment of the disclosure.

### DETAILED DESCRIPTION

Exemplary embodiments of the disclosure will be described in more detail below with reference to the accompanying drawings. Although the exemplary embodiments of the disclosure are shown in the drawings, it should be understood that the disclosure may be implemented in various forms and should not be limited to the specific embodiments set forth herein. On the contrary, the embodiments are provided to enable a more thorough understanding of the disclosure and to fully convey the scope of the disclosure to those skilled in the art.

In the following description, numerous specific details are given to provide a more thorough understanding of the disclosure. However, it will be apparent to those skilled in the art that the disclosure may be implemented without one or more of these details. In other examples, some technical features well known in the art are not described in order to avoid confusion with the disclosure. That is, not all of the features of the actual embodiments are described herein and well-known functions and structures are not described in detail.

In the drawings, the dimensions of layers, regions, elements and their relative dimensions may be exaggerated for clarity. The same reference numerals denote the same elements throughout.

It should be understood that when an element or layer is referred to as “on”, “adjacent to”, “connected to” or “coupled to” another element or layer, it may be directly on the other element or layer, adjacent to the other element or layer, connected to, or coupled to the other element or layer, or there may be an intermediate element or layer therebetween. Conversely, when an element is described as “directly on”, “directly adjacent to”, “directly connected to” or “directly coupled to” another element or layer, there is no intermediate element or layer therebetween. It should be understood that, although the terms first, second, third, and the like may be used to describe various elements, components, regions, layers, and/or portions, the elements, components, regions, layers, and/or portions should not be limited by these terms. These terms are used only to distinguish one element, component, region, layer, or portion from another element, component, region, layer, or portion. Thus, a first element, component, region, layer, or portion discussed below may be represented as a second element, component, region, layer, or portion without departing from the teachings of the disclosure. The discussion of a second element, component, region, layer or portion does not imply that a first element, component, region, layer or portion is necessarily present in the disclosure.

Spatially relational terms such as “below”, “under”, “lower”, “beneath”, “above”, and “upper” may be used herein for conveniently describing a relationship between one element or feature and another element or feature illustrated in the figures. It is to be understood that, in addition to the orientation shown in the figures, the spatial relationship terms tend to further include different orientations of devices in use and operation. For example, if the device in the drawings is turned over, an element or feature described as being “below” or “under” or “beneath” another element will be oriented as being “above” the other element or feature. Therefore, the exemplary terms “under” and “below” may include both up and down orientations. The device may be additionally oriented (rotated 90 degrees or otherwise) and the spatial terms used herein are interpreted accordingly.

The terms used herein are intended to describe specific embodiments only and are not to be a limitation of the disclosure. As used herein, the singular forms of “a”, “an” and “said/the” are also intended to include the plural forms, unless the context clearly indicates otherwise. It should also be understood that the terms “consist of” and/or “comprise/include” used in this specification mean that said features, integers, steps, operations, elements and/or components are present, but the presence or addition of one or more other features, integers, steps, operations, elements, components and/or groups is not excluded. As used herein, the term “and/or” includes any of the listed items and all combinations thereof.

In order to fully understand the disclosure, detailed operations and detailed structures will be set forth in the following description in order to explain the technical solution of the disclosure. Preferred embodiments of the disclosure are described in detail below. However, the disclosure may have other embodiments except these detailed descriptions.

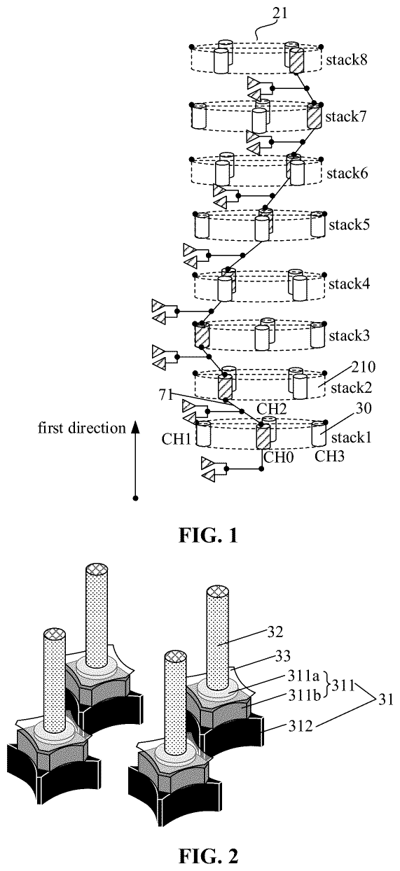

The embodiments of the disclosure provide a semiconductor structure. FIG. 1 is a schematic diagram of a semiconductor structure provided by an embodiment of the disclosure.

As shown in FIG. 1, the semiconductor structure includes a plurality of dies 21.

The plurality of dies 21 are stacked sequentially along a first direction. The first direction is a direction perpendicular to a plane of the dies 21.

Each of the plurality of dies 21 includes a base 210 and n first conductive structures 30.

The n first conductive structures 30 penetrate the base 210 along the first direction, and n is greater than or equal to 2.

In at least one group of the corresponding first conductive structures 30 in all the dies 21, projections of the first conductive structures 30 of two adjacent layers of the dies 21 along the first direction are not overlapped with each other.

In the embodiment of the disclosure, the projections of the corresponding first conductive structures in two adjacent layers of the dies are not overlapped with each other, which indicate that the corresponding first conductive structures in two adjacent layers of the dies are staggered at a certain angle. In this way, a same signal rotates and rises in the structure formed by stacking the plurality of dies, which can reduce crosstalk between different signals. Meanwhile, a spatial structure is optimized, and a higher bandwidth memory can be formed.

In an embodiment, the base 210 may be a silicon substrate, a germanium substrate, a silicon germanium substrate, a silicon carbide substrate, a silicon on insulator (SOI) substrate or a germanium on insulator (GOI) substrate, etc. The base 210 may also be a substrate including another element semiconductor or compound semiconductor, such as a glass substrate or a Group III-V compound substrate (such as a gallium nitride substrate or a gallium arsenide substrate, etc.). The base 210 may also be a laminated structure, such as Si/SiGe, etc., and may also be other epitaxial structure, such as a germanium on insulator (SGOI), etc.

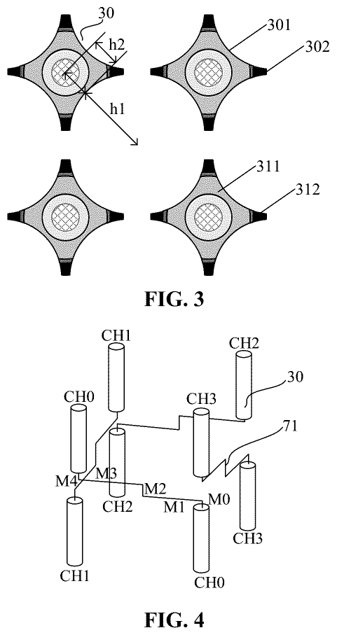

FIG. 2 is a spatial diagram of first conductive structures provided by an embodiment of the disclosure. FIG. 3 is a schematic diagram of the first conductive structures provided by the embodiment of the disclosure.

In an embodiment, as shown in FIG. 2 and FIG. 3, each of the first conductive structures 30 includes a first conductive bump 31. The first conductive bump 31 includes at least one concave surface 301. The concave surfaces 301 on adjacent first conductive bumps 31 are arranged opposite to each other.

In the embodiments of the disclosure, when a signal passes through one first conductive bump, the parasitic RLC is introduced into other first conductive bumps around this one first conductive bump due to the edge field radiation effect, which is inversely proportional to the distance. The edge field radiation effect weakens with the increase of the distance. Therefore, by arranging the concave surfaces of adjacent first conductive bumps opposite to each other, an overlapping range of the edge fields in space is weakened, thereby reducing parasitic parameters caused by the edge field radiation. Meanwhile, the first conductive bump is configured to include at least one concave surface, so that the volume of the first conductive bump is reduced, thereby reducing the parasitic capacitance of the first conductive bump itself.

In an embodiment, the plurality of first conductive structures 30 are arranged in square arrangement. For the plurality of first conductive structures 30 arranged in square arrangement, concave surfaces 301 of first conductive bumps 31 of two first conductive structures 30 at diagonal positions of the square arrangement are opposite to each other.

In the embodiment, the concave surfaces of the first conductive bumps at diagonal positions are arranged opposite to each other. Therefore, the distance between the first conductive bumps is increased, so that the edge field between the first conductive bumps is reduced, thereby reducing the parasitic parameters of RLC.

In an embodiment, referring to FIG. 3, each of the first conductive bumps 31 further includes at least one convex surface 302 adjacent to the concave surface 301. The convex surface is provided for facilitating subsequent soldering of the first conductive structure, thereby ensuring soldering quality of the first conductive bump 31.

In an embodiment, as shown in FIG. 3, in each square arrangement, a distance from an intersection point of diagonal lines to the concave surface 301 of each of the first conductive bumps 31 is a first distance h1, and a distance from the concave surface 301 of the first conductive bump 31 to a center of the first conductive bump 31 is a second distance h2. A ratio of the first distance h1 to the second distance h2 is 5:3 to 5:2.

If the ratio of the first distance to the second distance is set too large, it means that the concave surface of the first conductive bump is too close to the center of the first conductive bump, so that an area of the first conductive bump is too small, which affects conductive performance of the first conductive bump. If the ratio of the first distance to the second distance is set too small, it means that the concave surface of the first conductive bumps is close to the intersection point of the diagonal lines, so that a distance between two adjacent ones of the first conductive bumps is reduced, which increases the parasitic parameters. Therefore, the ratio of the first distance to the second distance is set as 5:3 to 5:2, which not only ensures the conductive performance of the first conductive bumps, but also reduces the parasitic parameters.

In an embodiment, as shown in FIG. 2, each of the first conductive structures 30 further includes a first through-silicon via 32 and a first test pad 33. The first through-silicon via 32 is located on the first conductive bump 31 and the first test pad 33 is located between the first through-silicon via 32 and the first conductive bump 31.

The first through-silicon via and the first conductive bump ensure electrical connection between the base and the die stack subsequently. The first test pad may be used for testing functions.

A conductive material inside the first through-silicon vias 32 includes, but is not limited to, Cu. The conductive material is wrapped with an insulating material, including, but not limited to, SiO₂. A material of the first test pads 33 includes, but is not limited to, Al.

In an embodiment, as shown in FIG. 3, each of the first conductive bumps 31 includes a first solder pad 311 and a first solder ball 312. The first solder pad 311 is located on the first solder ball 312. An orthographic projection of the first solder pad 311 on the base is located in an orthographic projection of the first solder ball 312 on the base.

As shown in FIG. 2, the first solder pad 311 includes a first sub-solder pad 311a and a second sub-solder pad 311b. The first sub-solder pad 311a is located on the second sub-solder pad 311b. A volume of the first sub-solder pad 311a is smaller than a volume of the second sub-solder pad 311b.

In some embodiments, during forming the first sub-solder pad 311a and the second sub-solder pad 311b, an insulating layer is formed on the first test pad. The insulating layer covers the first test pad. Then the insulating layer is exposed to form an opening on the first test pad. That is to say, a depth of the opening is equal to a thickness of the insulating layer on the first test pad, and a width of the opening may be smaller than a width of the first test pad, so that the volume of the first sub-solder pad 311a is smaller and the volume of the second sub-solder pad 311b is larger. If an opening with a larger width is to be formed during exposure, for example, the width of the opening is larger than the width of the first test pad, the depth of the opening increases, and an exposure pattern may be affected by diffuse reflection during exposure, resulting in the abnormal exposure pattern. Therefore, the first sub-solder pad 311a with a smaller volume is formed and the second sub-solder pad 311b with a larger volume is formed. It is to be noted that, the first sub-solder pad 311a and the second sub-solder pad 311b may be formed synchronously.

In an embodiment, the projections of the first conductive structures 30 in two adjacent layers of the dies 21 along the first direction are not overlapped with each other, including that projections of the first through-silicon vias 32 of the first conductive structures 30 in the two adjacent layers of the dies 21 along the first direction are not overlapped with each other.

In an embodiment, the semiconductor structure further includes first interconnects 71. The corresponding first conductive structures 30 in two adjacent layers of the dies 21 are connected through the first interconnects 71. By forming the first interconnects 71 in the dies, connection of the corresponding first conductive structures 30 arranged spirally is implemented, thereby ensuring normal signal transmission.

Specifically, as shown in FIG. 4, for example, four first conductive structures 30, namely CH0, CH1, CH2 and CH3, may be included in each layer of the dies. The corresponding CH0s in respective layers of the dies are connected through the first interconnects 71 and spiral up at a certain angle. Meanwhile, CH1 s, CH2s and CH3s are likewise connected through the first interconnects 71 and spiral up at a certain angle respectively. The first interconnects connecting two corresponding first conductive structures in the same layer are deflected at a certain angle, which reduce the opposite area of the first interconnects to each other, and thus reducing the crosstalk between the first interconnects.

In an embodiment, one end of each of the first interconnects is connected with the first through-silicon via, and the other end of the first interconnect is connected with the first conductive bump.

The first interconnects are metal wires, as shown in FIG. 4, including metal wires M0 to M4.

As shown in FIG. 4, one end of the first interconnect 71 is M0, and M0 is connected with the first through-silicon via or the first conductive bump of one first conductive structure in one layer of the die, and the other end M4 is connected with the first conductive bump or the first through-silicon via of the corresponding first conductive structure in the adjacent layer of the die. That is, one end is connected with the first through-silicon via, and the other end is connected with the first conductive bump, and vice versa. M0 and M4 are connected by M1, M2 and M3.

It should be interpreted that the end face of CH0 in the lower layer of the die connected by M0 and the end face of CH0 in the upper layer of the die connected by M4 should be on the same horizontal plane in FIG. 4, that is, the first interconnects should be parallel to the plane of the dies.

In an embodiment, the n first conductive structures 30 are located on a same circumference. The projections of the corresponding first conductive structures 30 in two adjacent layers of the dies 21 in the first direction are not overlapped with each other.

In the embodiment, the projections of the corresponding first conductive structures in two adjacent layers of the dies are not overlapped with each other, that is, all the first conductive structures spiral up at a certain angle, thus minimizing the crosstalk between different signals to a greatest extend.

In an embodiment, lines connecting the projections of the corresponding first conductive structures 30 in two adjacent layers of the dies 21 with a center of the circumference respectively form a preset angle, and the preset angle ranges from 30° to 90°.

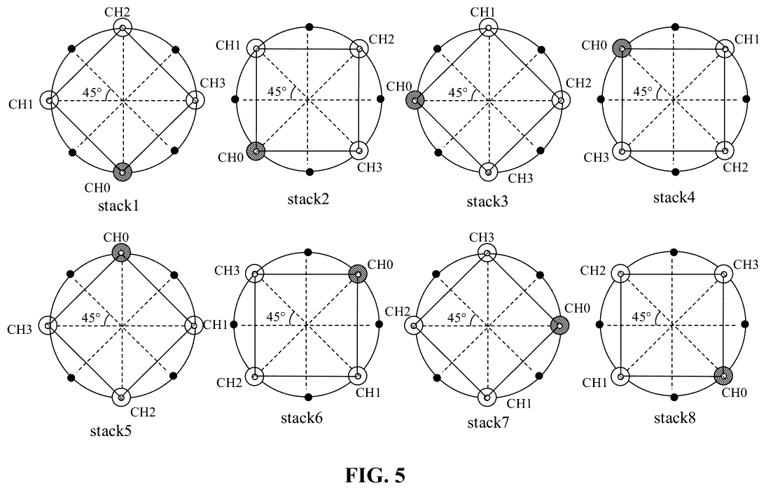

More specifically, the preset angle may be 45°. When the preset angle is 45°, the first conductive structures 30 arranged in square arrangement in each layer of the dies 21 have only two arrangements as shown in FIG. 5. That is, when the first conductive structures 30 in the odd-numbered layers of the dies 21 are shown as stack 1, stack 3, stack 5 and stack 7 in FIG. 5, the first conductive structures 30 in the even-numbered layers of the dies 21 are shown as stack 2, stack 4, stack 6 and stack 8 in FIG. 5, and vice versa. In this way, while it is ensured to shorten the lengths of the first interconnects and reduce the crosstalk, complexity of the process is reduced. Moreover, CH0s in two adjacent layers of the dies are not disposed face-to-face. Similarly, CH1 s, CH2s and CH3s in two adjacent layers of the dies are not disposed face-to-face either. Therefore, the opposite areas of the corresponding first conductive structures in the two adjacent layers of the dies are reduced, and thus reducing the signal crosstalk and parasitic capacitance.

As shown in FIGS. 1 and 4, the first conductive structures 30 (e.g. CH0 and CH1) in the semiconductor structure are spirally arranged along the stacking direction instead of vertically arranged. Therefore, the distance, between two adjacent layers of the dies, of the same first conductive structure 30 (e.g. CH0) is increased. If the first conductive structures 30 (e.g. CH0 and CH1) in the semiconductor structure are vertically arranged, all of the first conductive structures 30 in the dies (stack1 to stack8) will generate the signal crosstalk due to the edge field effect. Meanwhile, as the first conductive structures 30 are vertically arranged, that is, the distance between two adjacent layers of the dies (e.g. stack1 to stack2) of the same first conductive structures 30 are relatively close, which will cause the superposition of the crosstalk effects. Moreover, the superposition of the crosstalk effects increases with the length of the signal formed by the first conductive structures 30, which will eventually lead to signal distortion in the top layer of the dies (stack8).

In the embodiment, since the first conductive structures 30 (e.g. CH0 and CH1) are spirally arranged, that is, the distance between two adjacent layers of the dies, of the same first conductive structures 30 (e.g. CH0) is increased. When two different signals cross-talk in the same die (e.g. stack1), the crosstalk effect will not be superimposed on another die (e.g. stack2), thus mitigating the influence of crosstalk on signals.

As shown in FIG. 1 and FIG. 4, the first conductive structures 30 may be through-silicon via structures, and CH0 and CH1 may represent different through-silicon vias, i.e. through-silicon vias for transmitting different signals.

In an embodiment, the corresponding first conductive structures 30 in respective layers of the dies 21 spiral up at the preset angle along a preset direction in a direction perpendicular to a plane of the base 210. The preset direction is clockwise or counterclockwise.

When the corresponding first conductive structures in respective layers of the dies spiral up only in the clockwise direction or counterclockwise direction, the first interconnects in each layer may be made into a same structure, which reduce the process difficulty.

In an embodiment, as shown in FIG. 6, each of the dies 21 further includes a second conductive structure 40, which is located at a center of the circumference formed by the n first conductive structures 30 and penetrates the base 210 along the first direction.

The semiconductor structure further includes second interconnects 72. The second conductive structures 40 in two adjacent layers of the dies 21 are connected through the second interconnects 72. In some embodiments, each of the second interconnects 72 includes, for example, a solder pad and a solder ball structure, to achieve connection of the second conductive structures 40.

Each layer of the dies is provided with one second conductive structure, and in the embodiment, the first conductive structures are signal conductive structures, and the second conductive structure is a dummy conductive structure. Therefore, the second conductive structures connected through the second interconnects form a dummy TSV channel, which enable to dissipate heat generated by the first conductive structures in each layer of the dies, such that the heat dissipation mode becomes heat dissipation to a central point, thus increasing heat dissipation efficiency and improving device performance.

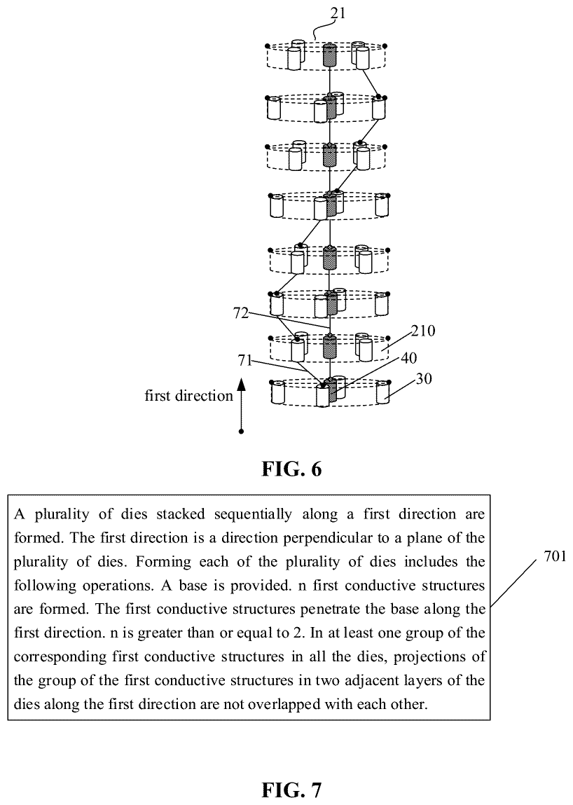

Embodiments of the disclosure also provide a method for manufacturing a semiconductor structure. Reference is made to FIG. 7 for details. As shown in FIG. 7, the method includes the following operation.

In S701, a plurality of dies stacked sequentially along a first direction are formed. The first direction is a direction perpendicular to a plane of the dies.

Forming each of the plurality of dies includes the following operations.

A base is provided.

n first conductive structures are formed. The first conductive structures penetrate the base along the first direction. n is greater than or equal to 2.

In at least one group of the corresponding first conductive structures in all the dies, projections of the group of the first conductive structures of two adjacent layers of the dies along the first direction are not overlapped with each other.

The method for manufacturing a semiconductor structure provided by the embodiments of the disclosure will be described in further detail below with reference to the specific embodiments.

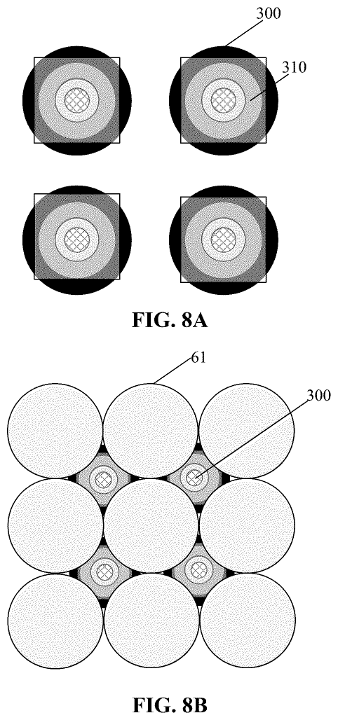

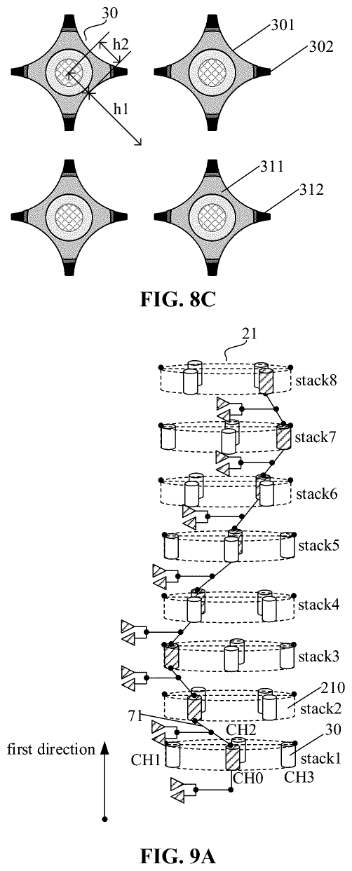

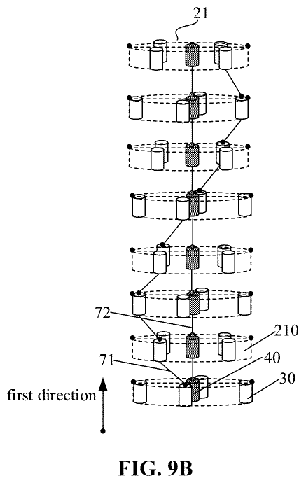

FIGS. 8A to 9B are schematic structural diagrams during a process for manufacturing a semiconductor structure provided by an embodiment of the disclosure.

Referring to FIGS. 8A to 8C, a process for manufacturing the first conductive structures is described in detail.

Forming the first conductive structures 30 includes the following operations.

Initial first conductive structures 300 are formed. Each of the initial first conductive structures 300 includes an initial first conductive bump 310 of a circular shape

At least one first mask layer 61 is formed on each of the initial first conductive bumps 310. The first mask layer 61 covers part of a periphery of the initial first conductive bump 310.

Part of the initial first conductive bump 310 covered by the at least one first mask layer 61 is etched to form the first conductive structure 30.

In an embodiment, each of the first mask layers 61 has a circular shape, so that each of the first conductive bumps 310 formed after the initial first conductive bump 310 is partially etched includes at least one concave surface.

It is to be understood that, the first mask layers may also be of another arc-shaped structure.

In an embodiment, the first conductive structures 30 are arranged in square arrangement. For the plurality of first conductive structures 30 of each square arrangement, the concave surfaces 301 of the first conductive bumps 31 of two first conductive structures 30 at diagonal positions of the square arrangement are opposite to each other.

In the embodiment, the concave surfaces of the first conductive bumps at diagonal positions are opposite to each other. Therefore, the distance between the first conductive bumps is increased, so that the edge field between the first conductive bumps is reduced, thereby reducing the parasitic parameters of RLC.

In an embodiment, referring to FIG. 8C, each of the first conductive bumps 31 further includes at least one convex surface 302 disposed adjacent to the concave surface 301. The convex surface is provided to facilitate subsequent soldering of the first conductive structures, thereby ensuring soldering quality of the first conductive bumps 31.

In an embodiment, as shown in FIG. 8C, in each square arrangement, a distance from an intersection point of diagonal lines to the concave surface 301 of each of the first conductive bumps 31 is a first distance h1, and a distance from the concave surface 301 of the first conductive bump 31 to a center of the first conductive bump 31 is a second distance h2. A ratio of the first distance h1 to the second distance h2 is 5:3 to 5:2.

If the ratio of the first distance to the second distance is set too large, it means that the concave surface of the first conductive bump is too close to the center of the first conductive bump, so that an area of the first conductive bump is too small, which affects conductive performance of the first conductive bump. If the ratio of the first distance to the second distance is set too small, it means that the concave surface of the first conductive bumps is close to the intersection point of the diagonal lines, so that a distance between two adjacent ones of the first conductive bumps is reduced, which increases the parasitic parameters. Therefore, the ratio of the first distance to the second distance is set as 5:3 to 5:2, which not only ensures the conductive performance of the first conductive bumps, but also reduces the parasitic parameters.

In an embodiment, as shown in FIG. 2, each of the first conductive structures 30 further includes a first through-silicon via 32 and a first test pad 33. The first through-silicon via 32 is located on the first conductive bump 31 and the first test pad 33 is located between the first through-silicon via 32 and the first conductive bump 31.

The first through-silicon via and the first conductive bump ensure electrical connection between the base and the die stack subsequently. The first test pad may be used for testing functions.

A conductive material inside the first through-silicon vias 32 includes, but is not limited to, Cu. The conductive material is wrapped with an insulating material, including, but not limited to, SiO₂. A material of the first test pads 33 includes, but is not limited to, Al.

In an embodiment, as shown in FIG. 8C, each of the first conductive bumps 31 includes a first solder pad 311 and a first solder ball 312. The first solder pad 311 is located on the first solder ball 312. An orthographic projection of the first solder pad 311 on the base 210 is located in an orthographic projection of the first solder ball 312 on the base 210.

As shown in FIG. 2, the first solder pad 311 includes a first sub-solder pad 311a and a second sub-solder pad 311b. The first sub-solder pad 311a is located on the second sub-solder pad 311b. A volume of the first sub-solder pad 311a is smaller than a volume of the second sub-solder pad 311b.

The first sub-solder pad is connected with the first test pad, so that the smaller volume of the first sub-solder pad can reduce a contact area with the first test pad, thereby reducing the contact resistance.

Next, referring to FIG. 9A and FIG. 9B, a connection mode of the dies in the die stack manufactured by the above method may be improved to further reduce RLC parasitic parameters.

Referring to FIG. 9A, S701 is performed in which a plurality of dies 21 stacked sequentially along a first direction are formed. The first direction is a direction perpendicular to a plane of the dies 21. Forming each of the plurality of dies includes the following operations. A base 210 is provided. n first conductive structure 30 are formed that penetrate the base 210 in a first direction, where n is greater than or equal to 2. In at least one group of the corresponding first conductive structures 30 in the dies 21, projections of two groups of the first conductive structures 30 of two adjacent layers of the dies 21 are not overlapped with each other in the first direction.

In an embodiment, the base 210 may be a silicon substrate, a germanium substrate, a silicon germanium substrate, a silicon carbide substrate, a silicon on insulator (SOI) substrate or a germanium on insulator (GOI) substrate, etc. The base 210 may also be a substrate including another element semiconductor or compound semiconductor, such as a glass substrate or a Group III-V compound substrate (such as a gallium nitride substrate or a gallium arsenide substrate, etc.). The base 210 may also be a laminated structure, such as Si/SiGe, etc., and may also be another epitaxial grown structure, such as a germanium on insulator (SGOI), etc.

In an embodiment, the projections of the first conductive structures 30 of two adjacent layers of the dies 21 in the first direction are not overlapped with each other, including that projections of the first through-silicon vias 32 of the first conductive structures 30 of the dies 21 along the first direction are not overlapped with each other.

Referring further to FIG. 9A, the method further includes the following operations. First interconnects 71 are formed after each layer of the dies 21 is formed. The corresponding first conductive structures 30 in two adjacent layers of the dies 21 are connected through the first interconnects 71.

Specifically, as shown in FIG. 4, for example, four first conductive structures 30, namely CH0, CH1, CH2 and CH3, may be included in each layer of the dies. The corresponding CH0s in respective layers of the dies are connected through the first interconnects 71 and spiral up at a certain angle. Meanwhile, CH1 s, CH2s and CH3s are likewise connected through the first interconnects 71 and spiral up at a certain angle respectively. The first interconnects connecting two corresponding first conductive structures in the same layer are deflected at a certain angle which reduce the opposite area of the first interconnects to each other, and thus reducing crosstalk between the first interconnects.

In an embodiment, one end of each of the first interconnects is connected with the first through-silicon via, and the other end of the first interconnect is connected with the first conductive bump.

The first interconnects are metal wires, as shown in FIG. 4, including metal wires M0 to M4.

As shown in FIG. 4, one end of the first interconnects 71 is M0, and M0 is connected with the first through-silicon via of or the first conductive bump of one first conductive structure in one layer of the die, and the other end M4 is connected with the first conductive bump or the first through-silicon via of the corresponding first conductive structure in the adjacent layer of the die. That is, one end is connected with the first through-silicon via, and the other end is connected with the first conductive bump, and vice versa. M0 and M4 are connected by M1, M2 and M3.

It should be interpreted that the end face of CH0 in the lower layer of the die connected by M0 and the end face of CH0 in the upper layer of the die connected by M4 should be on the same horizontal plane in FIG. 4, that is, the first interconnects should be parallel to the plane of the dies.

In an embodiment, the n first conductive structures 30 are located on a same circumference. The projections of the corresponding first conductive structures 30 in two adjacent layers of the dies 21 in the first direction are not overlapped with each other.

In the embodiment, the projections of the corresponding first conductive structures in two adjacent layers of the dies are not overlapped with each other, that is, all the first conductive structures spiral up at a certain angle, thus minimizing the crosstalk between different signals to a greatest extend.

In an embodiment, lines connecting the projections of the corresponding first conductive structures 30 in two adjacent layers of the dies 21 with a center of the circumferences respectively form a preset angle, and the preset angle ranges from 30° to 90°.

More specifically, the preset angle may be 45°. When the preset angle is 45°, the first conductive structures 30 arranged in square arrangement in each layer of the dies 21 have only two arrangements as shown in FIG. 5. That is, when the first conductive structures 30 in the odd-numbered layers of the dies 21 are shown as stack 1, stack 3, stack 5 and stack 7 in FIG. 5, the first conductive structures 30 in the even-numbered layers of the dies 21 are shown as stack 2, stack 4, stack 6 and stack 8 in FIG. 5, and vice versa. In this way, while it is ensured to shorten the lengths of the first interconnects and reduce the crosstalk, complexity of the process is reduced. Meanwhile, CH0s in two adjacent layers of the dies are not disposed face-to-face. Similarly, CH1 s, CH2s and CH3s in two adjacent layers of the dies are not disposed face-to-face either. Therefore, the opposite areas of the corresponding first conductive structures in the two adjacent layers of the dies are reduced, and thus reducing the signal crosstalk and parasitic capacitance.

In an embodiment, the corresponding first conductive structures 30 in respective layers of the dies 21 spiral up at the preset angle along a preset direction in a direction perpendicular to a plane of the base 210. The preset direction is clockwise or counterclockwise.

When the corresponding first conductive structures in respective layers of the dies spiral up only in the clockwise direction or counterclockwise direction, the first interconnects in each layer may be made into a same structure, which reduce the process difficulty.

Next, referring to FIG. 9B, forming each of the dies 21 further includes the following operation.

A second conductive structure 40 is formed. The second conductive structure 40 is located at a center of the circumference formed by the n first conductive structures 30 and penetrates the base 210 along the first direction.

The method further includes forming second interconnects 72. The second conductive structures 40 in two adjacent layers of the dies 21 are connected through the second interconnects 72.

Each layer of the dies is provided with one second conductive structure, and in the embodiment, the first conductive structures are signal conductive structures, and the second conductive structure is a dummy conductive structure. Therefore, the second conductive structures connected through the second interconnects form a dummy TSV channel, which enable to dissipate heat generated by the first conductive structures in each layer of the dies, such that the heat dissipation mode becomes heat dissipation to a central point, thus increasing heat dissipation efficiency and improving device performance.

The above is only the preferred embodiments of the disclosure, and is not intended to limit the protection scope of the disclosure. Any modification, equivalent replacement and improvement made within the spirit and principles of the disclosure shall be included in the protection scope of the disclosure.

In the embodiment of the disclosure, the projections of the corresponding first conductive structures in two adjacent layers of the dies are not overlapped with each other, which indicates that the corresponding first conductive structures in two adjacent layers of the dies are staggered at a certain angle. Therefore, a same signal spiral up in the structure formed by stacking a plurality of dies, which can reduce the crosstalk between different signals. Meanwhile, a spatial structure is optimized, and a higher bandwidth memory can be formed.

1. A semiconductor structure, comprising:
a plurality of dies, stacked sequentially along a first direction, the first direction being a direction perpendicular to a plane of the plurality of dies; wherein,
each of the plurality of dies comprises:
a base; and
n first conductive structures penetrating the base along the first direction, wherein n is greater than or equal to 2; wherein,
in at least one group of the corresponding first conductive structures in all the dies, projections of the group of the corresponding first conductive structures in two adjacent layers of the dies along the first direction are not overlapped with each other.

2. The semiconductor structure of claim 1, further comprising:
first interconnects, wherein the corresponding first conductive structures in two adjacent layers of the dies are connected through the first interconnects.

3. The semiconductor structure of claim 1, wherein
the n first conductive structures are located on a same circumference;
in a projection in the first direction, projections of the corresponding first conductive structures in two adjacent layers of the dies are not overlapped with each other.

4. The semiconductor structure of claim 3, wherein
lines connecting the projections of the corresponding first conductive structures in two adjacent layers of the dies with a center of a projection of the circumference respectively form a preset angle, and the preset angle ranges from 30° to 90°.

5. The semiconductor structure of claim 4, wherein
the corresponding first conductive structures in respective layers of the dies spiral up at the preset angle along a preset direction in the first direction, wherein the preset direction is clockwise or counterclockwise.

6. The semiconductor structure of claim 2, wherein
each of the first conductive structures comprises a first through-silicon via and a first conductive bump, the first through-silicon via is located on the first conductive bump, the first through-silicon via penetrates the base along the first direction, and the first conductive bump is located between two adjacent layers of the dies.

7. The semiconductor structure of claim 6, wherein
the first conductive bump comprises at least one concave surface; the concave surfaces on the adjacent first conductive bumps are opposite to each other.

8. The semiconductor structure of claim 6, wherein
one end of each of the first interconnects is connected with the first through-silicon via, and the other end of the first interconnect is connected with the first conductive bump.

9. The semiconductor structure of claim 3, wherein
each of the dies further comprises a second conductive structure located at a center of the circumference formed by the n first conductive structures and penetrating the base along the first direction.

10. The semiconductor structure of claim 9, further comprising:
second interconnects, the second conductive structures in two adjacent layers of the dies being connected through the second interconnects.

11. The semiconductor structure of claim 9, wherein
the first conductive structures are signal conductive structures, and the second conductive structure is a dummy conductive structure.

12. A method for manufacturing a semiconductor structure, comprising:
forming a plurality of dies stacked sequentially along a first direction, the first direction being a direction perpendicular to a plane of the plurality of dies; wherein
forming each of the plurality of dies comprises:
providing a base; and
forming n first conductive structures, the first conductive structures penetrating the base along the first direction, n being greater than or equal to 2; wherein,
in at least one group of the corresponding first conductive structures in all the dies, projections of the group of the first conductive structures in two adjacent layers of the dies along the first direction are not overlapped with each other.

13. The method of claim 12, further comprising:
forming first interconnects after forming each layer of the dies, wherein the corresponding first conductive structures in two adjacent layers of the dies are connected through the first interconnects.

14. The method of claim 12, wherein,
the n first conductive structures are located on a same circumference; and
in a projection in the first direction, projections of the corresponding first conductive structures in two adjacent layers of the dies are not overlapped with each other.

15. The method of claim 14, wherein,
forming each of the plurality of dies further comprises:
forming a second conductive structure, the second conductive structure being located at a center of the circumference formed by the n first conductive structures and penetrating the base along the first direction.

16. The method of claim 15, further comprising:
forming second interconnects, wherein the second conductive structures in two adjacent layers of the dies are connected through the second interconnects.
